(19) United States
(12) Patent Application Publication
(10) Pub. No.: US 2017/0051409 A1
(43) Pub. Date: Feb. 23, 2017

(54) THIN FILM DEPOSITION APPARATUS

(71) Applicants: Young Jin NOH, Suwon-si (KR); Dong Min SON, Hwaseong-si (KR); Jae Myung CHOE, Seoul (KR); Jae Young AHN, Seongnam-si (KR); Cheol Kyu YANG, Suwon-si (KR)

(72) Inventors: Young Jin NOH, Suwon-si (KR); Dong Min SON, Hwaseong-si (KR); Jae Myung CHOE, Seoul (KR); Jae Young AHN, Seongnam-si (KR); Cheol Kyu YANG, Suwon-si (KR)

(21) Appl. No.: 15/164,915

(22) Filed: May 26, 2016

(30) Foreign Application Priority Data
Aug. 19, 2015 (KR) 10-2015-0116482

(51) Int. Cl. C23C 16/455; C23C 16/458

(52) U.S. Cl. CPC C23C 16/45574; C23C 16/458

(57) ABSTRACT

A thin film deposition apparatus, including a processing chamber; a boat in the processing chamber, the boat to accommodate a plurality of substrates therein; and a nozzle to supply a source gas to the processing chamber to form a thin film on each of the substrates, the nozzle including a plurality of T-shaped nozzle pipes, each of the T-shaped nozzle pipes including a first pipe having closed ends and a second pipe coupled to a middle portion of the first pipe.

### CROSS-REFERENCE TO RELATED APPLICATION

This application claims priority to and benefit of Korean Patent Application No. 10-2015-0116482, filed on Aug. 19, 2015, in the Korean Intellectual Property Office, the disclosure of which is incorporated by reference herein in its entirety.

### BACKGROUND

1. Field

Embodiments relate to a thin film deposition apparatus used in the manufacturing of a semiconductor device.

2. Description of the Related Art

As a degree of integration of semiconductor devices may increase, in a semiconductor manufacturing process, it may be required to form fine patterns having high aspect ratios.

### SUMMARY

Embodiments may be realized by providing a thin film deposition apparatus, including a processing chamber; a boat in the processing chamber, the boat to accommodate a plurality of substrates therein; and a nozzle to supply a source gas to the processing chamber to form a thin film on each of the substrates, the nozzle including a plurality of T-shaped nozzle pipes, each of the T-shaped nozzle pipes including a first pipe having closed ends and a second pipe coupled to a middle portion of the first pipe.

The nozzle may include the plurality of T-shaped nozzle pipes spaced apart from each other adjacent to a side surface of the boat.

The first and second pipes may be coupled to each other to form a substantially right angle.

A plurality of the first pipes may be linearly adjacent to the side surface of the boat.

Each the first pipes may include a plurality of nozzle holes to sequentially dispense the source gas laterally from each the first pipes, and each of the second pipes may be shorter than the first pipe to which the second pipe is respectively coupled.

Each of the plurality of nozzle holes may correspond to a space between the plurality of substrates.

The plurality of T-shaped nozzle pipes may be coupled to each other to be linearly adjacent to the side surface of the boat.

Each of the first pipes may include a first end having a protrusion and a second end having a recess, and a protrusion of a first first pipe and a recess of a second first pipe may be coupled to each other.

The plurality of T-shaped nozzle pipes may include a first T-shaped nozzle pipe to supply the source gas to a lower region of the boat, a second T-shaped nozzle pipe to supply the source gas to a central region of the boat, and a third T-shaped nozzle pipe to supply the source gas to an upper region of the boat.

The processing chamber may include a plurality of the nozzles.

Each of the plurality of nozzles may sequentially supply a different source gas.

The nozzle may further include injection portions respectively connected to the second pipes; and a coupling portion fixing the injection portions to each other.

Embodiments may be realized by providing a thin film deposition apparatus, including a processing chamber; a boat in the processing chamber, the boat to accommodate a plurality of substrates therein; and a plurality of nozzle parts including a plurality of T-shaped nozzle pipes spaced apart from each other adjacent to a side surface of the boat to supply a source gas and a purge gas to form a thin film on each of the substrates to different regions of the processing chamber.

Each of the plurality of T-shaped nozzle pipes may include a first pipe having a plurality of nozzle holes and a second pipe coupled to a middle portion of the first pipe to form a substantially right angle.

One of the plurality of nozzle parts may supply the purge gas, and a remainder of the plurality of nozzle parts may supply the source gas.

Embodiments may be realized by providing a thin film deposition apparatus, including a processing chamber; and a plurality of nozzle pipes to supply gas to different regions of the processing chamber at substantially uniform velocities.

Each of the nozzle pipes may include a first pipe having closed ends and a second pipe coupled to a middle portion of the first pipe.

The plurality of nozzle pipes may be disposed vertically.

The plurality of nozzle pipes may include at least three nozzles disposed vertically.

Each nozzle pipe may include a separate injection portion to individually supply the gas to each of the nozzle pipes, the separate injection portions respectively connected to the second pipes.

### BRIEF DESCRIPTION OF THE DRAWINGS

Features will become apparent to those of skill in the art by describing in detail exemplary embodiments with reference to the attached drawings in which:

FIG. 1 illustrates a schematic cross-sectional view of an atomic layer deposition (ALD) apparatus according to an example embodiment;

FIG. 2 illustrates a view of a portion of the atomic layer deposition apparatus according to the example embodiment illustrated in FIG. 1;

FIGS. 3 and 4 illustrate views of respective nozzle parts of an atomic layer deposition apparatus according to example embodiments;

FIGS. 5 and 6 illustrate views of respective nozzle parts and gas supply apparatuses of an atomic layer deposition apparatus according to an example embodiment;

FIGS. 7 and 8 illustrate a flow chart and a timing diagram of a process of forming a thin film using an atomic layer deposition apparatus according to an example embodiment, respectively;

FIG. 9 illustrates a schematic perspective view of a memory cell structure of a vertical memory device manufactured by using an atomic layer deposition apparatus according to an example embodiment;

FIGS. 10A and 10B illustrate enlarged views of Area A of FIG. 9; and

FIGS. 11 through 18 illustrate views of stages in a method of manufacturing a vertical memory device by using an atomic layer deposition apparatus according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Throughout the specification, it will be understood that when an element, such as a layer, region or substrate, is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc., may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the example embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, example embodiments will be described with reference to schematic views. In the drawings, for example, due to manufacturing techniques and/or tolerances, modifications of the shape shown may be estimated. Thus, example embodiments should not be construed as being limited to the particular shapes of regions shown herein, for example, to include a change in shape results in manufacturing. The following embodiments may also be constituted as one or a combination thereof.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure) is illustrated in a cross-sectional view, an electronic device may include a plurality of the device structures (e.g., memory cell structures), as would be illustrated by a plan view of the electronic device. The plurality of device structures may be arranged in an array and/or in a two-dimensional pattern.

The contents of example embodiments described below may have a variety of configurations and propose only a required configuration herein, but are not limited thereto.

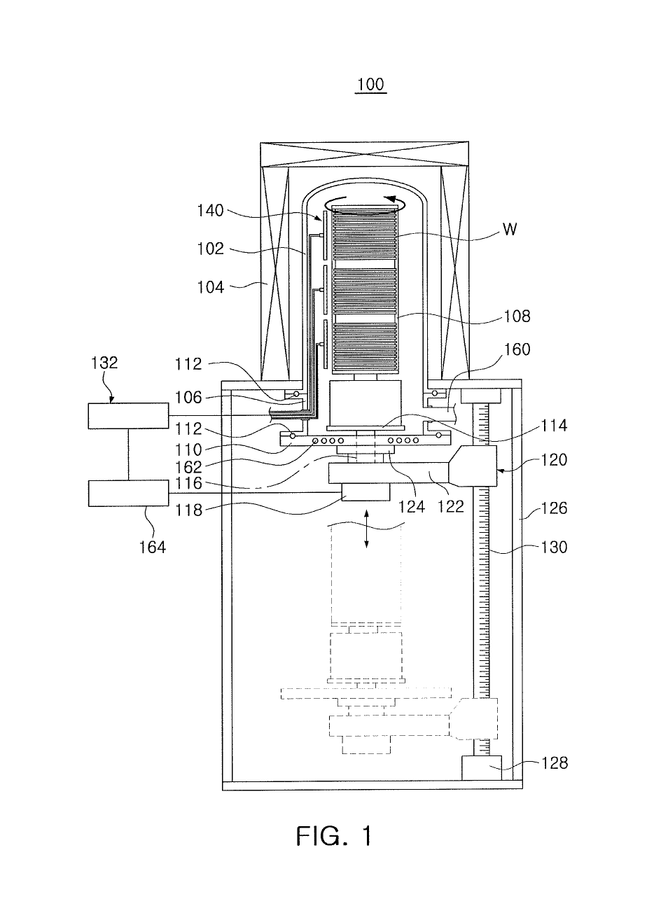

FIG. 1 illustrates a schematic cross-sectional view of an atomic layer deposition (ALD) apparatus according to an example embodiment.

Referring to FIG. 1, an atomic layer deposition apparatus 100 according to an example embodiment may include a processing chamber 102, a manifold 106, a boat 108, a nozzle part 140, a gas supply apparatus 132, a controller 164, a vertical driver 120, and a rotary driver 118.

The processing chamber 102 may extend vertically, may have an upper portion having a dome shape and a lower portion having an open cylinder shape, and may include a quartz or silicon carbide (SiC) material that may withstand high temperatures. A heating portion 104 heating the processing chamber 102 may be disposed to surround the processing chamber 102.

The manifold 106 may be coupled on a lower portion of the processing chamber 102, may include a metallic material, and may have a cylinder shape having open upper and lower portions.

The manifold 106 may include an exhaust portion 160 provided in a side thereof to discharge, for example, surplus source gas, purge gas, and reaction by-products. The exhaust portion 160 may be connected to a vacuum pump.

The boat 108 may accommodate a plurality of semiconductor substrates W at specific intervals in a vertical direction. The boat 108 may be carried into the processing chamber 102 or out of the processing chamber 102 through the manifold 106. The semiconductor substrates W may be accommodated in the boat 108 to be loaded into the processing chamber 102, and then a lower opening of the manifold 106 may be closed by a lid member 110. An internal space of the manifold 106 may have a relatively low temperature as compared to an internal space of the processing chamber 102. In order to compensate for such a temperature difference, a heater 162 may be provided in the lid member 110. For example, the heater 162 may heat an internal space of the manifold 106 such that internal spaces of the processing chamber 102 and the manifold 106 may have uniform temperature distribution. The heater 162 may be formed using an electrical resistance heating wire.

The processing chamber 102 and the manifold 106, as well as the manifold 106 and the lid member 110, may have a sealing member 112 interposed therebetween to provide a seal, respectively.

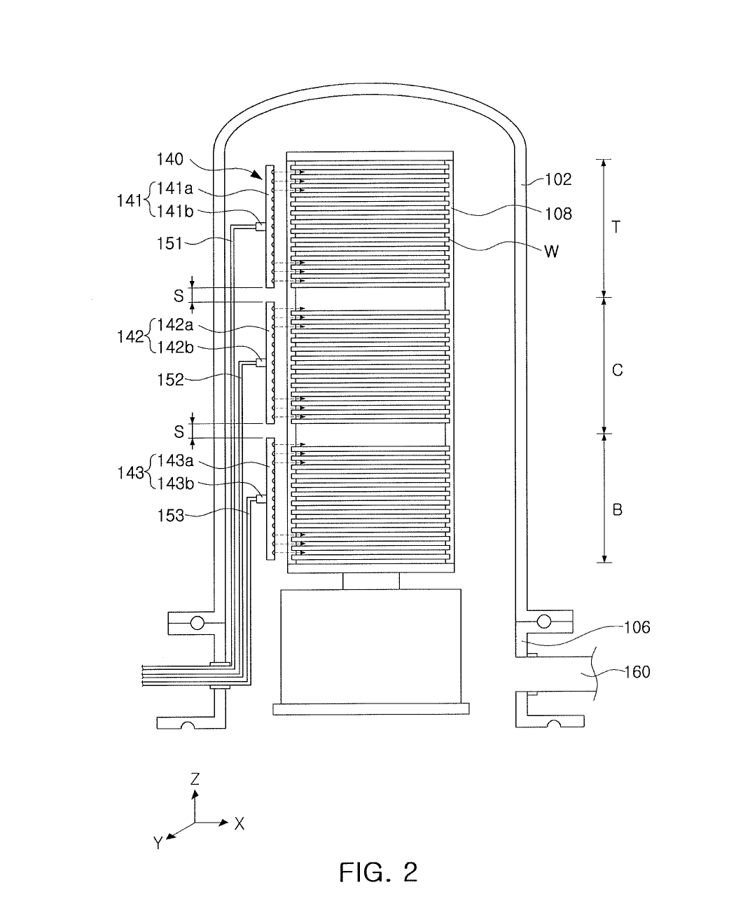

The nozzle part 140 may supply a source gas forming thin films on the semiconductor substrates W, respectively, and a purge gas for purging the interior of the processing chamber 102 of the source gas, to the processing chamber 102, and may include a plurality of T-shaped nozzle pipes. End portions of the nozzle part 140 will be described below in more detail with reference to FIGS. 2 through 4.

A gas supply apparatus 132 may be disposed to connect to the nozzle part 140, and may include storage parts storing the source gas (or a liquid source material) and the purge gas, an evaporator evaporating a liquid source material, and a valve controlling gas supply.

A controller 164 may control operations of the gas supply apparatus 132, a vertical driver 120, and a rotary driver 118. After the boat 108 in which a plurality of semiconductor substrates W are stacked is carried into the processing chamber 102 by the vertical driver 120, the controller 164 may control supply flow rates and supply times of gases supplied by the gas supply apparatus 132, and may adjust the rotational speed of the semiconductor substrates W using the rotary driver 118 in order to form a thin film having a uniform thickness on each of the substrates W.

The boat 108 may be disposed on a turntable 114, and the turntable 114 may be coupled above a rotary shaft 116. The rotary shaft 116 may be connected to the turntable 114 and the rotary driver 118. The rotary driver 118 may be disposed on a lower portion of a horizontal arm 122 of the vertical driver 120, and the lid member 110 may be disposed above the horizontal arm 122 of the vertical driver 120. The rotary driver 118 may include a first motor. Rotational force of the first motor may be transmitted to the rotary shaft 116. The rotary driver 118 may rotate the turntable 114 and the boat 108. A mechanical seal 124 preventing leakage through a gap between the rotary shaft 116 and the lid member 110 may be disposed between the lid member 110 and the horizontal arm 122.

The load-lock chamber 126 may be disposed below the processing chamber 102, and the boat 108 may move vertically between the processing chamber 102 and the load-lock chamber 126.

The vertical driver 120 may include the horizontal arm 122, a vertical driving portion 128 providing driving power for moving the horizontal arm 122 vertically, and a driving shaft 130 transmitting the driving power. The vertical driving portion 128 may include a second motor. The driving shaft 130 may be used with a lead screw that is rotated by rotational force of the second motor. The horizontal arm 122 may be coupled to the driving shaft 130, and may move vertically by rotation of the driving shaft 130.

In the example embodiment, the atomic layer deposition apparatus 100 is exemplified as a thin film deposition apparatus. In examples embodiments are not limited thereto, and various types of deposition apparatuses able to deposit thin films using a source gas may be used without restriction.

FIG. 2 illustrates a view of a portion of the atomic layer deposition apparatus according to the example embodiment illustrated in FIG. 1. FIG. 2 illustrates a view of the nozzle part 140 in the processing chamber 102 of the atomic layer deposition apparatus 100 of FIG. 1.

Referring to FIG. 2, the nozzle part 140 may include a plurality of T-shaped nozzle pipes 141, 142, and 143. In the example embodiment, the nozzle part 140 may include three T-shaped nozzle pipes 141, 142, and 143 simultaneously supplying a source gas to three different regions of the processing chamber 102. The nozzle part 140 may include a first T-shaped nozzle pipe 141 supplying the source gas to an upper region T of the boat 108, a second T-shaped nozzle pipe 142 supplying the source gas to a central region C of the boat 108, and a third T-shaped nozzle pipe 143 supplying the source gas to a lower region B of the boat 108. The number of T-shaped nozzle pipes is not limited to the number of the T-shaped nozzle pipes illustrated in the example embodiment. When the processing chamber 102 is divided into four or more regions, four or more T-shaped nozzle pipes may form the nozzle part 140.

Each of the T-shaped nozzle pipes 141, 142, and 143 may include first pipes 141a, 142a, and 143a each having closed ends, and second pipes 141b, 142b, and 143b each coupled to a middle portion of each of the first pipes 141a, 142a, and 143a, i.e., the nozzle pipes may be T-shaped.

The plurality of T-shaped nozzle pipes 141, 142, and 143 may be disposed to be spaced apart from each other at specific intervals S, e.g., in a y-axis direction, adjacently, e.g., adjacent, to the side surface of the boat 108 in which the plurality of semiconductor substrates W is accommodated, e.g., in a y-axis direction. The plurality of first pipes 141a, 142a, and 143a may be disposed at specific intervals S, e.g., in a y-axis direction, in a linear manner, adjacently to the side surface of the boat 108. The first pipes 141a, 142a, and 143a and the second pipes 141b, 142b, and 143b may be coupled to each other to substantially form a right angle, e.g., to form a substantially right angle. The lengths of the second pipes 141b, 142b, and 143b, e.g., in a y-axis direction, may be shorter than the lengths of the first pipes 141a, 142a, and 143a, e.g., in an x-axis direction, respectively.

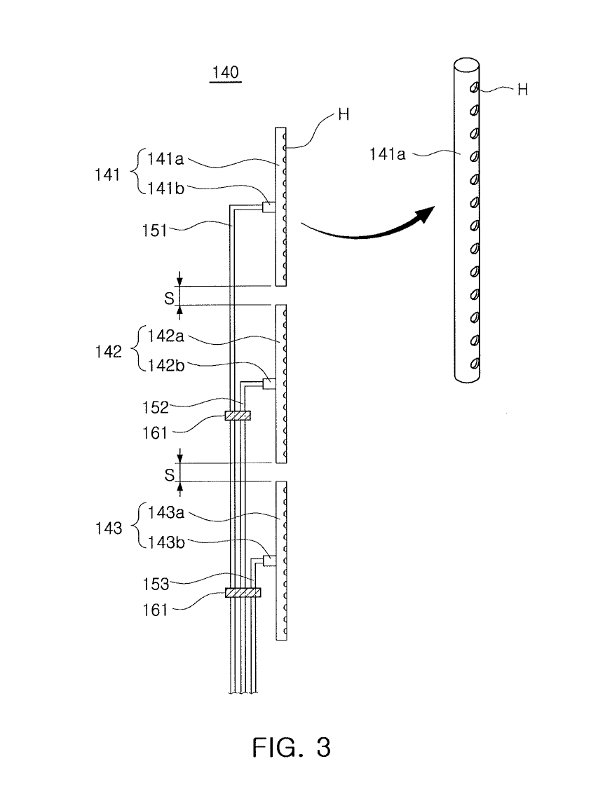

Each of the first pipes 141a, 142a, and 143a may have a plurality of nozzle holes H provided in the side thereof at specific intervals to spray a source gas (see FIG. 3). Each of the plurality of nozzle holes H may correspond to each of spaces between the semiconductor substrates W, e.g., may correspond to a space between the semiconductor substrates W. The nozzle holes H may be provided at, e.g., in, an amount at least equal to the number of the semiconductor substrates W.

The nozzle part 140 may have further injection portions 151, 152, and 153 respectively connected to the second pipes 141b, 142b, and 143b of the T-shaped nozzle pipes 141, 142, and 143. A source gas may be individually introduced into the T-shaped nozzle pipes 141, 142, and 143 through the injection portions 151, 152, and 153, respectively, and may be sprayed into the processing chamber 102 through the nozzle holes H.

The atomic layer deposition apparatus 100 according to the example embodiment may include the nozzle part 140 including three T-shaped nozzle pipes 141, 142, and 143 simultaneously supplying a source gas to three different regions of the processing chamber 102, for example, upper, central, and lower regions T, C, and B, and thin films respectively formed on semiconductor substrates by the atomic layer deposition apparatus 100 may have improved thickness variations in the regions of the processing chamber 102 and improved thickness variations in the semiconductor substrates, as compared to thin films respectively formed on semiconductor substrates by an atomic layer deposition apparatus including a single L-type nozzle pipe. The source gas may be individually supplied to the three T-shaped nozzle pipes 141, 142, and 143, the velocity of the source gas sprayed through the nozzle holes H may be increased, and the velocity of the source gas may remain constant throughout the entire region of the processing chamber 102, as compared to supplying the source gas to a single L-type nozzle pipe. Such a result may also be confirmed through a simulation.

Unlike the example embodiment, the second pipes 141b, 142b, and 143b of the T-shaped nozzle pipes 141, 142, and 143 may be connected to a single injection portion. There may be no effect of an improvement in thickness variations in a thin film when a source gas is introduced through the single injection portion.

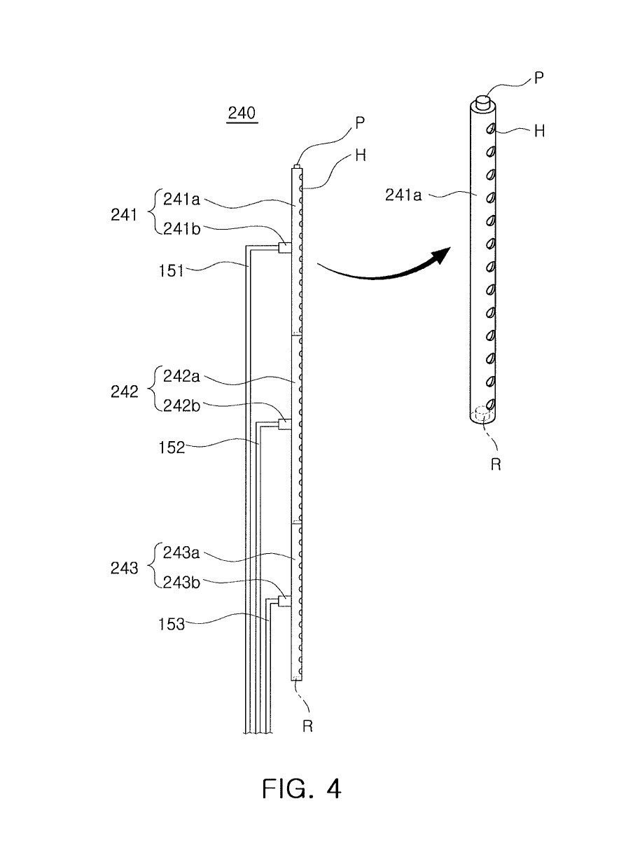

FIGS. 3 and 4 illustrate views of respective nozzle parts of an atomic layer deposition apparatus according to example embodiments.

Referring to FIG. 3, the nozzle part 140 may include the injection portions 151, 152, and 153 respectively connected to the second pipes 141b, 142b, and 143b of the T-shaped nozzle pipes 141, 142, and 143, and may further include coupling portions 161 fixing the injection portions 151, 152, and 153 to each other. The number of the nozzle holes H provided laterally in each of the first pipes 141a, 142a, and 143a is not limited to the number of the nozzle holes H illustrated in the example embodiment, and may be changed according to the number of semiconductor substrates W accommodated in the boat 108 (refer to FIG. 2).

At least one coupling portion 161 may be installed between the first and second injection portions 151 and 152, and among the first, second, and third injection portions 151, 152, and 153, respectively. The at least one coupling portion 161 may allow the plurality of first pipes 141a, 142a, and 143a to be disposed at specific intervals S adjacently to the side surface of the boat 108 (refer to FIG. 2), and each of the plurality of nozzle holes H may be positioned to correspond to each of spaces between the semiconductor substrates W. The at least one coupling portion 161 may maintain an interval among the injection portions 151, 152, and 153.

The at least one coupling portion 161 may include a material, such as quartz or silicon carbide (SiC), in order to prevent damage caused by heat or a source gas during a process.

Referring first to FIG. 4, a nozzle part 240 may include a plurality of T-shaped nozzle pipes 241, 242, and 243 coupled to each other to be vertically arranged in a line adjacently to the side surface of the boat 108 (refer to FIG. 2).

Each of the T-shaped nozzle pipes 241, 242, and 243 may include first pipes 241a, 242a, and 243a each having closed ends, and second pipes 241b, 242b, and 243b each coupled to a middle portion of each of the first pipes 241a, 242a, and 243a. Each of the first pipes 241a, 242a, and 243a may include one end having a protrusion P, and the other end having a recess R. A protrusion P of a first pipe 242a and 243a and a recess R of another first pipe 241a and 242a may be coupled to each other. In such a manner, the first pipes 241a, 242a, and 243a may be coupled to each another to be vertically arranged in a line, e.g., may be in direct contact such that there is no specific intervals S therebetween. The protrusion P may fit into the recess R without space therebetween.

The first pipes 241a, 242a, and 243a and the second pipes 241b, 242b, and 243b may be coupled to each other to substantially form a right angle. The second pipes 241b, 242b, and 243b may be shorter than the first pipes 241a, 242a, and 243a, respectively.

The nozzle part 240 may further include the coupling portions 161 described with reference to FIG. 3, such that an interval among the injection portions 151, 152, and 153 respectively connected to the second pipes 241b, 242b, and 243b, may be maintained and each of the plurality of nozzle holes H may be positioned to correspond to each of spaces between the semiconductor substrates W.

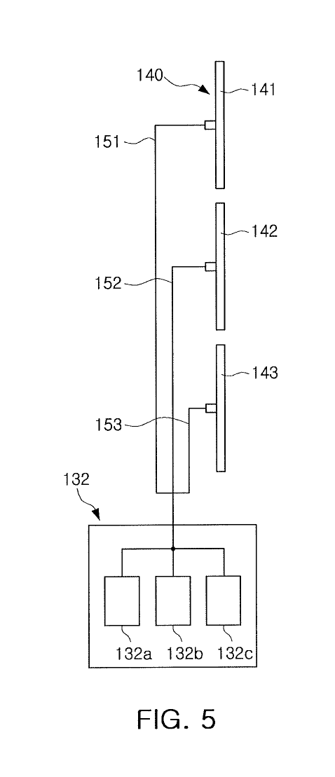

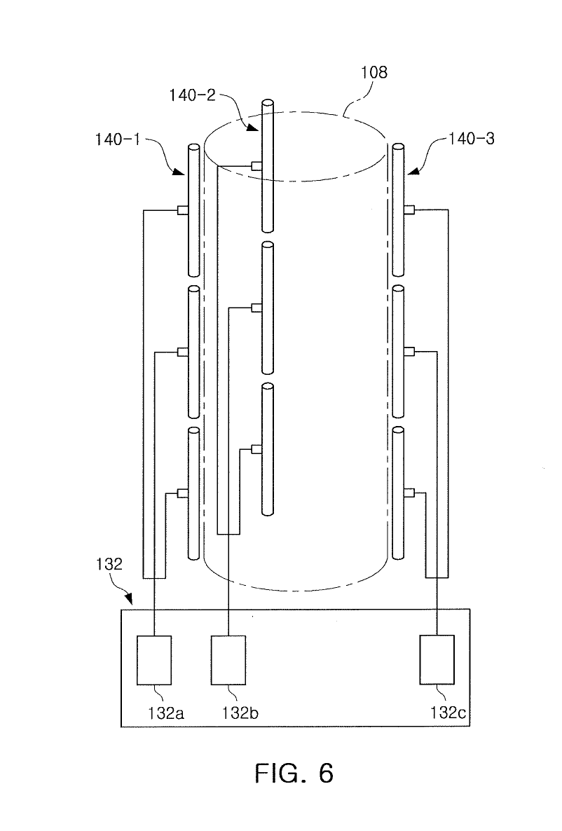

FIGS. 5 and 6 illustrate views of respective nozzle parts and gas supply apparatuses of an atomic layer deposition apparatus according to an example embodiment.

Referring to FIG. 5, the nozzle part 140 may include the plurality of T-shaped nozzle pipes 141, 142, and 143, and the injection portions 151, 152, and 153 respectively connected to the T-shaped nozzle pipes 141, 142, and 143. The injection portions 151, 152, and 153 may introduce the source gas and the purge gas supplied by the gas supply apparatus 132 into the T-shaped nozzle pipes 141, 142, and 143, respectively. The gas supply apparatus 132 may include a first gas supply apparatus 132a, a second gas supply apparatus 132b, and a third gas supply apparatus 132c. Each of the first, second and third gas supply apparatuses 132a, 132b, and 132c may include a storage part storing a source gas or a liquid source material and a valve adjusting gas supply. Each of the first, second and third gas supply apparatuses 132a, 132b, and 132c may further include an evaporator evaporating a liquid source material when evaporating the liquid source material and supplying the evaporated liquid source material as a source gas. The first and second gas supply apparatuses 132a and 132b may supply a first source gas and a second source gas, respectively, and the third gas supply apparatus 132c may supply a purge gas. In the example embodiment, the nozzle part 140 may supply the first source gas, the second source gas, or the purge gas to the upper, central, and lower regions T, C, and B of the boat 108 (refer to FIG. 2). The nozzle part 140 may sequentially supply the first source gas, the second source gas, and a purge gas in required order.

Referring to FIG. 6, a plurality of nozzle parts 140-1, 140-2, and 140-3 may be provided in the processing chamber 102 adjacently to the side surface of the boat 108. Each of the plurality of nozzle parts 140-1, 140-2, and 140-3 may include a plurality of T-shaped nozzle pipes and injection portions respectively connected to the T-shaped nozzle pipes.

The gas supply apparatus 132 may include the first gas supply apparatus 132a, the second gas supply apparatus 132b, and the third gas supply apparatus 132c. The first and second gas supply apparatuses 132a and 132b may supply first and second source gases, respectively, and the third gas supply apparatus 132c may supply a purge gas. In the example embodiment, the first nozzle part 140-1 may supply a first source gas introduced by the first gas supply apparatus 132a, the second nozzle part 140-2 may supply a second source gas introduced by the second gas supply apparatus 132b, and the third nozzle part 140-3 may supply a purge gas introduced by the third gas supply apparatus 132c. The first, second, and third nozzle parts 140-1, 140-2, and 140-3 may allow the first source gas, the second source gas, and the purge gas to be simultaneously supplied to the various regions of the boat 108, respectively.

In the example embodiment, use of the plurality of nozzle parts 140-1, 140-2, and 140-3 may allow different gases to be supplied to the processing chamber through separate nozzle parts. When the purge gas is supplied through a separate nozzle part, source gas may remain in the plurality of nozzle parts. By separating the plurality of nozzle parts supplying the source gas, foreign matter may be prevented from being generated when different types of source gas remaining in the nozzle part react with each other. The plurality of nozzle parts 140-1, 140-2, and 140-3 may allow the first source gas, the second source gas, and a purge gas to be sequentially supplied to the processing chamber in a required order.

Hereinafter, a method of forming a thin film using the atomic layer deposition apparatus 100 will be described, according to an example embodiment having the above-mentioned configuration and illustrated in FIG. 1. A method of forming a thin film using an atomic layer deposition (ALD) process using an atomic layer deposition apparatus will be described, according to an example embodiment. This may be an example, but a method of forming a thin film is not limited thereto.

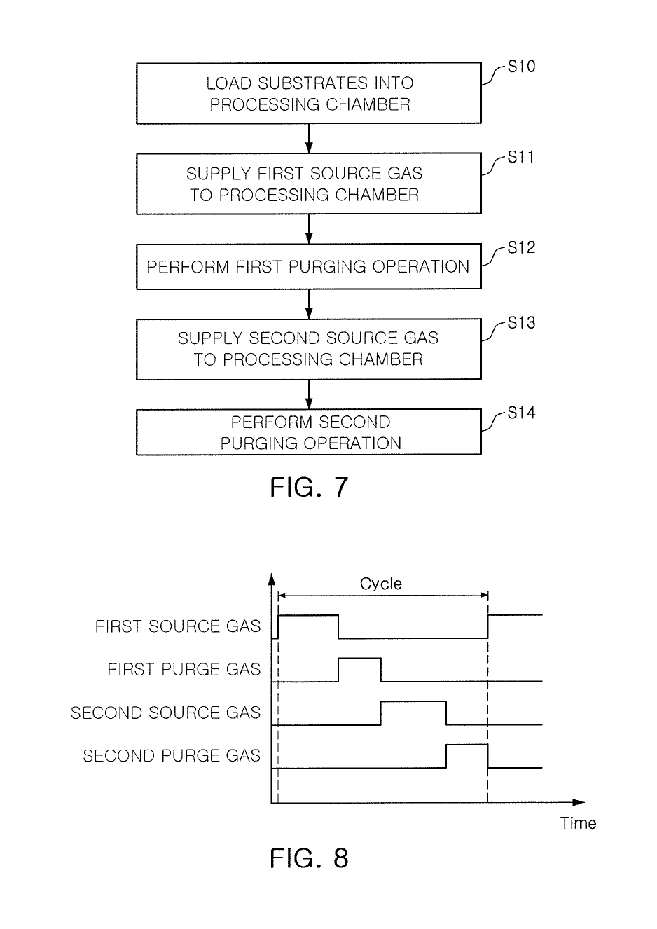

FIGS. 7 and 8 illustrate a flow chart and a timing diagram of a process of forming a thin film using an atomic layer deposition apparatus according to the example embodiment illustrated in FIG. 1, respectively.

Referring to FIGS. 1, 7, and 8, semiconductor substrates W may be held in the boat 108 to be loaded in the processing chamber 102 (S10). After the loading of the semiconductor substrates W, a vacuum pump connected to the exhaust portion 160 may form a desired vacuum condition in the processing chamber 102. Meanwhile, the heater 104 may heat the semiconductor substrates W to a desired processing temperature.

Next, the nozzle part 140 may allow a first source gas to be supplied to the processing chamber 102 (S11). The plurality of T-shaped nozzle pipes disposed vertically may allow the first source gas to be supplied to the entire region of the processing chamber 102 at a substantially uniform velocity. The first source gas may be supplied in a pulsed manner for a predetermined period of time to be adsorbed onto the semiconductor substrates W. The first source gas may be a precursor gas providing a material that forms a required thin film. The supplying of the first source gas in a pulsed manner for a predetermined period of time may means that the first source gas is only supplied at a constant flow rate for a predetermined period of time and is then shut off, and hereinafter may be used as having an identical meaning.

Subsequently, a first purging operation may be performed on the processing chamber 102 by introducing a first purge gas through the nozzle part 140 (S12). The first purging operation (S12) may allow a first source gas that is not adsorbed onto the semiconductor substrates W to be discharged through the exhaust portion 160. The first purge gas may be supplied for a predetermined period of time in a pulsed manner. The first purge gas may be used with an inert gas, such as argon (Ar) or helium (He). When the first purging operation (S12) is completed, only the first source gas of a single layer may be adsorbed onto the semiconductor substrates W.

Next, the nozzle part 140 may allow a second source gas to be supplied to the processing chamber 102 (S13). The plurality of T-shaped nozzle pipes disposed vertically may allow the second source gas to be supplied to the entire region of the processing chamber 102 at a substantially uniform velocity. The second source gas may be supplied in a pulsed manner for a predetermined period of time. The second source gas may react with the first source gas adsorbed onto the semiconductor substrates W to form a required thin film having a thickness of single atoms. The second source gas may be a reactant gas reacting with the first source gas that is the precursor gas.

Subsequently, a second purging operation may be performed on the processing chamber 102 by introducing a second purge gas through the nozzle part 140 (S14).

The second source gas that does not react by the second purging operation (S14) and reaction by-products may be discharged through the exhaust portion 160. The second purge gas may be used with an inert gas, such as argon (Ar) or helium (He).

Operations S11 through S14 may form a cycle, and the cycle may be repeated according to thicknesses of a required thin film.

When a thin film having a required thickness is formed, the semiconductor substrates W may be cooled and then unloaded from the processing chamber 102.

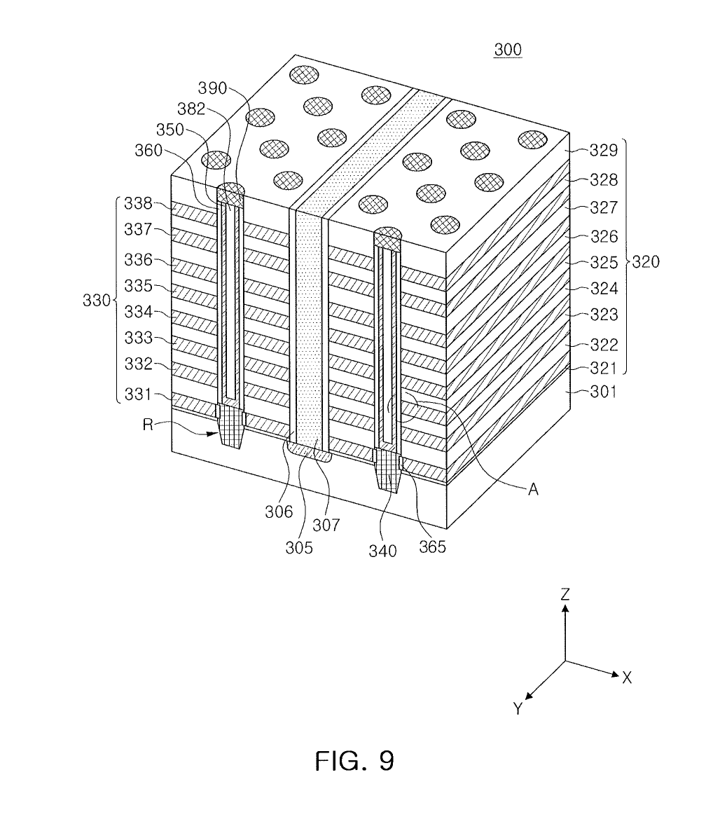

FIG. 9 illustrates a schematic perspective view of a memory cell structure of a vertical memory device manufactured using an atomic layer deposition apparatus according to an example embodiment.

Referring to FIG. 9, a vertical memory device 300 may include a substrate 301, gate structures including interlayer insulation layers 320 and gate electrodes 330 alternately stacked on the substrate 301, and channels 350 passing through the interlayer insulation layers 320 and gate electrodes 330 in a direction perpendicular to an upper surface of the substrate 301. The vertical memory device 300 may further include an epitaxial layer 340 disposed on the substrate 301 on lower portions of the channels 350, a gate dielectric layer 360 disposed between the channels 350 and the gate electrodes 330, a common source line 307 disposed on a source region 305, and a drain pad 390 disposed on an upper portion of each of the channels 350.

In the vertical memory device 300, a single memory cell string may be configured along each of the channels 350, and a plurality of memory cell strings may be arranged in rows and columns in x-axis and y-axis directions, respectively.

The substrate 301 may have an upper surface extending in the x-axis and y-axis directions. The substrate 301 may contain a semiconductor material, such as a group IV semiconductor, a group III-V compound semiconductor, or a group II-VI compound semiconductor. For example, the group IV semiconductor may contain silicon, germanium, or silicon-germanium. The substrate 301 may be provided as a bulk wafer or an epitaxial layer.

The channels 350 each having a column shape may be disposed to extend in a z-axis direction perpendicular to the upper surface of the substrate 301. Each of the channels 350 may have an annular shape surrounding a first insulation layer 382 in each channel 350. The channels 350 may be spaced apart from each other in the x-axis and y-axis directions to be disposed to create a specific arrangement. A deposition of adjacent channels 350 with the common source line 307 interposed therebetween may be symmetrical as illustrated in the example embodiment.

The channels 350 may be electrically connected to the substrate 301 through the epitaxial layer 340 on lower surfaces of the channels 350. The channels 350 may contain a semiconductor material, such as polycrystalline silicon, and the semiconductor material may not be doped with an impurity, or may contain a p- or n-type impurity.

The epitaxial layer 340 may be disposed on the substrate 301 on the lower portions of the channels 350. The epitaxial layer 340 may be disposed on a side surface of at least one gate electrode 330. Even though aspect ratios of the channels 350 are increased by the epitaxial layer 340, the channels 350 may be stably and electrically connected to the substrate 301. The epitaxial layer 340 may contain polycrystalline silicon, single crystalline silicon, polycrystalline germanium or single crystalline germanium that are doped or not with an impurity.

An epitaxial insulation layer 365 may be disposed between the epitaxial layer 340 and a gate electrode 331. The epitaxial insulation layer 365 may be an oxide film formed by thermally oxidizing a portion of the epitaxial layer 340. For example, the epitaxial insulation layer 365 may be a silicon oxide film SiO₂ formed by thermally oxidizing a silicon (Si) epitaxial layer 340.

The plurality of gate electrodes 331 to 338 collectively represented by 330 may be disposed to be spaced apart from the substrate 301 in the z-axis direction adjacently to a side surface of each of the channels 350. The gate electrodes 330 may contain polycrystalline silicon, a metal silicide material, or a metallic material. The metal silicide material may be, for example, a silicide material of a metal selected from cobalt (Co), nickel (Ni), hafnium (Hf), platinum (Pt), tungsten (W) and titanium (Ti), or combinations thereof. The metallic material may be, for example, tungsten (W), aluminum (Al), or copper (Cu).

Each of the plurality of interlayer insulation layers 321 to 329 collectively represented by 320 may be disposed between the gate electrodes 330. The interlayer insulation layers 320 may also be disposed to be spaced apart from each other in the z-axis direction and to extend in the y-axis direction as in the gate electrodes 330. The interlayer insulation layers 320 may contain an insulating material, such as silicon oxide or silicon nitride.

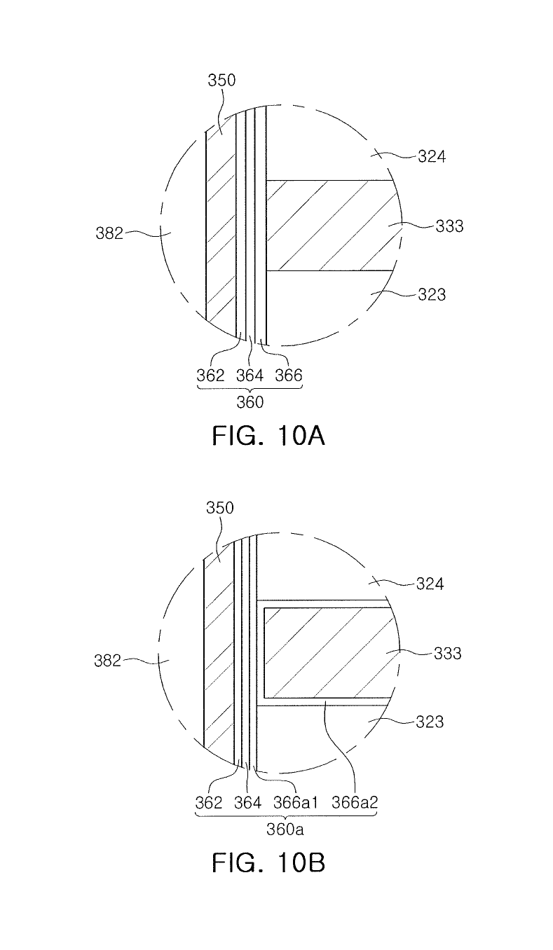

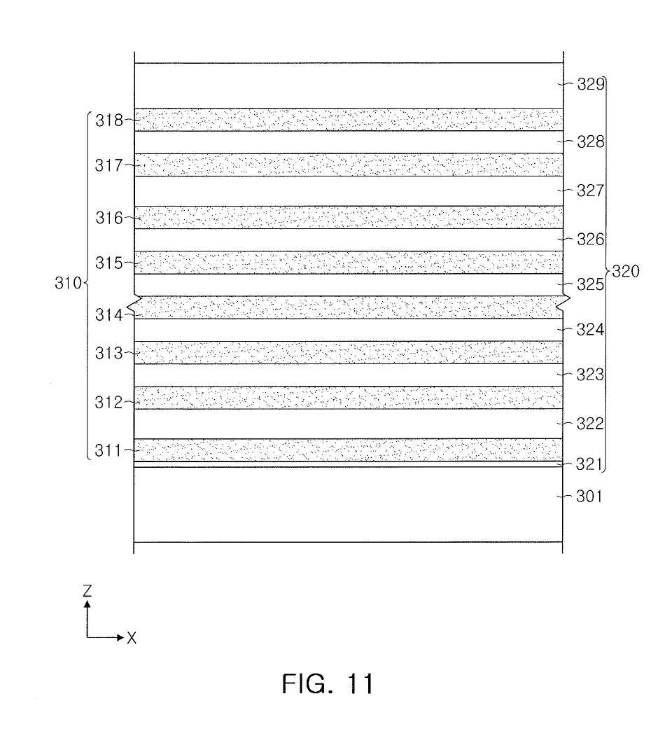

The gate dielectric layer 360 may be disposed between the gate electrodes 330 and the channels 350. The gate dielectric layer 360 may include a tunneling dielectric layer, a charge storage layer, and a blocking dielectric layer sequentially stacked from the channel 350. This will be described below in more detail with reference to FIGS. 10A and 10B.

FIGS. 10A and 10B are enlarged views of Area A of FIG. 9.

Referring to FIG. 10A, the gate dielectric layer 360 may have a structure in which a tunneling dielectric layer 362, a charge storage layer 364, and a blocking dielectric layer 366 are sequentially stacked from the channel 350. The gate dielectric layer 360 may be disposed such that all of the tunneling dielectric layer 362, the charge storage layer 364, and the blocking dielectric layer 366 may extend adjacently to the channel 350. A relative thickness of the layers forming the gate dielectric layer 360 is not limited to the thickness of the layers illustrated in FIG. 10A, and may be changed.

The tunneling dielectric layer 362 may contain silicon oxide. The charge storage layer 364 may contain silicon nitride or silicon oxynitride. The blocking dielectric layer 366 may contain silicon oxide, a metal oxide having a high dielectric constant, or combinations thereof. The metal oxide having a high dielectric constant may be, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃), or combinations thereof.

Referring to FIG. 10B, a gate dielectric layer 360a may have a structure in which the tunneling dielectric layer 362, the charge storage layer 364, and blocking dielectric layers 366a1 and 366a2 are sequentially stacked from the channel 350. Unlike the example embodiment of FIG. 10A, the blocking dielectric layers 366a1 and 366a2 may form two layers, a first blocking dielectric layer 366a1 may extend adjacently to the channel 350, and a second blocking dielectric layer 366a2 may be disposed to surround a gate electrode layer 333. For example, the first blocking dielectric layer 366a1 may be a silicon oxide film, and the second blocking dielectric layer 366 may be a metal oxide film having a high dielectric constant.

At an upper end of a memory cell string, each of the drain pads 390 may be disposed to cover an upper surface of the first insulation layer 382 and to be electrically connected to the channel 350. The drain pad 390 may contain, for example, doped polycrystalline silicon. The drain pad 390 may be electrically connected to bit lines formed on the drain pad 390.

At a lower end of the memory cell string, the source region 305 may be disposed in a region of the substrate 301. The source regions 305 may be disposed to be adjacent to an upper surface of the substrate 301 and to be spaced apart from the each other in the x-axis direction in a specific distance while extending in the y-axis direction. For example, the source regions 305 may be arranged sequentially, in every two channels 350 in the x-axis direction, but is not limited thereto. The common source line 307 may be disposed on the source region 305 in order to extend in the y-axis direction adjacently to the source region 305. The common source line 307 may contain a conductive material. For example, the common source line 307 may contain tungsten (W), aluminum (Al), or copper (Cu). The common source line 307 may be electrically isolated from the gate electrodes 330 by a second insulation layer 306.

FIGS. 11 through 19 illustrate views of a method of manufacturing a semiconductor device using an atomic layer deposition apparatus according to an example embodiment.

Referring to FIG. 11, interlayer sacrificial layers 311 to 316 collectively represented by 310 and the interlayer insulation layers 320 may be alternately stacked on the substrate 301. The interlayer insulation layers 320 and the interlayer sacrificial layers 310 may be alternately stacked on each other on the substrate 301 starting from a first interlayer insulation layer 321 as illustrated in FIG. 11.

The interlayer sacrificial layers 310 may be formed of a material that may be etched with etching selectivity for the interlayer insulation layers 320. For example, the interlayer insulation layers 320 may include at least one of silicon oxide and silicon nitride, and the interlayer sacrificial layers 310 may include a material selected from silicon, silicon carbide, silicon oxide, and silicon nitride, and different from the interlayer insulation layers 320.

As illustrated in the example embodiment, thicknesses of the interlayer insulation layers 320 may not all be identical. A bottom interlayer insulation layer 321 among the interlayer insulation layers 320 may be formed to have a relatively thin thickness, and a top interlayer insulation layer 329 may be formed to have a relatively thick thickness.

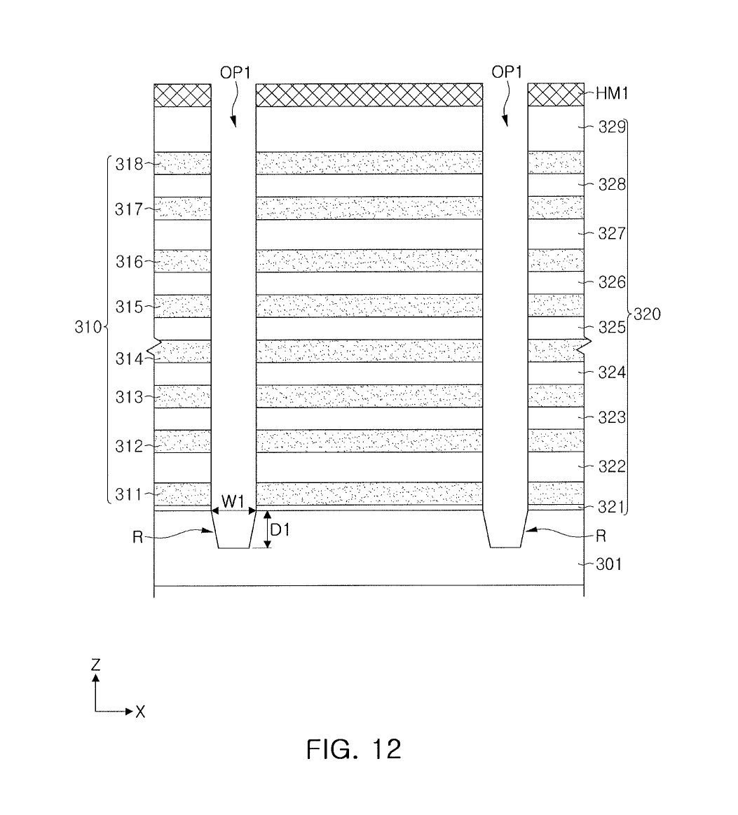

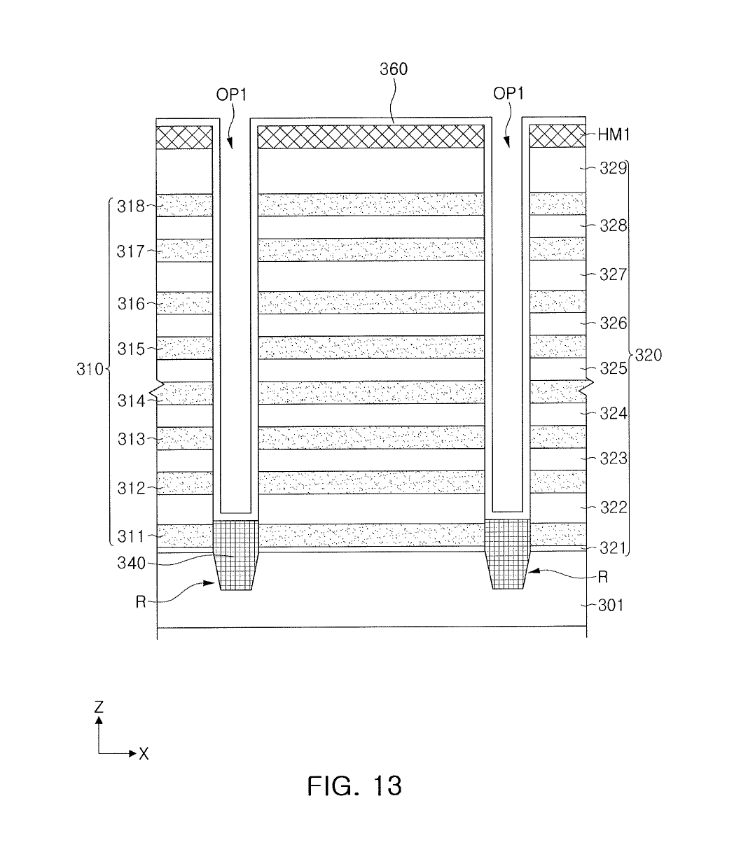

Referring to FIG. 12, first openings OP1 may pass through the interlayer sacrificial layers 310 and the interlayer insulation layers 320, have a hole shape, and have a high aspect ratio. The first openings OP1 may be referred to as ‘channel hole.’ The aspect ratios of the first openings OP1 may be 10:1 or more.

The first openings OP1 may extend to the substrate 301 in the z-axis direction to form recess regions R in the substrate 301. The first openings OP1 may be formed by anisotropically etching the interlayer sacrificial layers 310 and the interlayer insulation layers 320. Depths D1 of the recess regions R may be selected according to widths W1 of the first openings OP1.

Referring to FIG. 13, the epitaxial layer 340 may be formed in the recess regions R below lower portions of the first openings OP1.

The epitaxial layer 340 may be formed using a selective epitaxial growth (SEG) process. The epitaxial layer 340 may fill the recess regions R, and may extend above the substrate 301. An upper surface of the epitaxial layer 340 may be higher than that of a sacrificial layer 311 adjacent to the substrate 301, and may be lower than a lower surface of a sacrificial layer 312 above the sacrificial layer 311.

The upper surface of the epitaxial layer 340 may be flat as illustrated in the example embodiment. According to, for example, growth conditions, the upper surface of the epitaxial layer 340 may be inclined.

Subsequently, the first openings OP1 may have the gate dielectric layer 360 formed on inner walls thereof. The gate dielectric layer 360 may be conformally formed to have a uniform thickness on the inner walls of the first openings OP1 by atomic layer deposition (ALD) using the atomic layer deposition apparatus 100 illustrated in FIG. 1. Furthermore, a plurality of vertical memory devices may be formed on a single substrate 301, and thickness variations of the gate dielectric layer 360 may be improved even between the plurality of vertical memory devices.

A method of forming the gate dielectric layer 360 having a stack structure illustrated in FIG. 10A will be described in more detail with reference to FIGS. 1 and 7.

The first openings OP1 may have the blocking dielectric layer 366, the charge storage layer 364, and the tunneling dielectric layer 362 sequentially stacked therein.

First, the first openings OP1 may have the blocking dielectric layer 366 formed on the inner walls thereof. The blocking dielectric layer 366 may be metal oxide having a high dielectric constant, and the metal oxide may be formed by atomic layer deposition (ALD) using the atomic layer deposition apparatus 100 illustrated in FIG. 1.

Referring to FIGS. 1 and 7, the substrate 101 having the first openings OP1 may be held in the boat 108 to be loaded into the processing chamber 102 (S10), and a metal source gas, a first source gas, may be supplied to the processing chamber 102 in a pulsed manner for a predetermined period of time through the nozzle part 140 (S11). The metal source gas may be an organic compound containing a metal element. The metal source gas may contain aluminum (Al), hafnium (HO, zirconium (Zr), lanthanum (La), or tantalum (Ta). The metal source gas may be adsorbed onto the inner walls of the first openings OP1, the upper surface of the epitaxial layer 340, and an upper surface of a hard mask HM1. Subsequently, a first purge gas may be supplied to the processing chamber 102 through the nozzle part 140 to perform a first purging operation (S12).

Next, an oxygen source gas, a second source gas, may be supplied to the processing chamber 102 through the nozzle part 140 (S13). The oxygen source gas may be oxygen O₂, ozone O₃, water vapor H₂O, or hydrogen peroxide H₂O₂. The oxygen source gas may react with the previously adsorbed metal source gas to conformally form a metal oxide having an atomic layer thickness on the inner walls of the first openings OP1, the upper surface of the epitaxial layer 340, and the upper surface of the hard mask HM1. Subsequently, a second purge gas may be supplied to the processing chamber 102 through the nozzle part 140 to perform a second purging operation (S14).

By repeating the operations (S11 through S14) according to required thicknesses, the blocking dielectric layer 366 including metal oxide may be formed.

Second, the charge storage layer 364 may be formed on the blocking dielectric layer 366 formed on the inner walls of the first openings OP1. The charge storage layer 364 may be silicon nitride, and the silicon nitride may be formed by atomic layer deposition (ALD) using the atomic layer deposition apparatus 100 illustrated in FIG. 1.

Referring to FIGS. 1 and 7, while the substrate 301, in which the blocking dielectric layer 366 is formed on the inner wall of the first opening OP1, is loaded into the processing chamber 102, a silicon source gas, a first source gas, may be supplied to the processing chamber 102 in a pulsed manner for a predetermined period of time through the nozzle part 140 (S11). The silicon source gas may be an organic or inorganic compound incorporating a silicon element. The silicon source gas may contain, for example, hexachlorodisilane (HCDS) or diisopropylaminosilane (DIPAS). The silicon source gas may be adsorbed onto the blocking dielectric layer 366 on the inner walls of the first opening OP1, the upper surface of the epitaxial layer 340, and the upper surface of the hard mask HM1. Subsequently, the first purge gas may be supplied to the processing chamber 102 through the nozzle part 140 to perform a first purging operation (S12).

Next, a nitrogen source gas, a second source gas, may be supplied to the processing chamber 102 through the nozzle part 140 (S13). The nitrogen source gas may be one of nitrogen N₂ and ammonia NH₃. The nitrogen source gas may react with the previously adsorbed silicon source gas to conformally form the silicon nitride having an atomic layer thickness on the blocking dielectric layer 366 on the inner walls of the first openings OP1, the upper surface of the epitaxial layer 340, and the upper surface of the hard mask HM1. Subsequently, a second purge gas may be supplied to the processing chamber 102 through the nozzle part 140 to perform a second purging operation (S14).

By repeating the operations (S11 through S14) according to required thicknesses, the charge storage layer 364 including silicon nitride may be formed.

Third, the tunneling dielectric layer 362 may be formed on the charge storage layer 364 formed on the inner walls of the first opening OP1. The tunneling dielectric layer 362 may be silicon oxide, and the silicon oxide may be formed by atomic layer deposition (ALD) using the atomic layer deposition apparatus 100 illustrated in FIG. 1.

Referring to FIGS. 1 and 7, while the substrate 301, on which the blocking dielectric layer 366 and the charge storage layer 364 are formed on the inner walls of the first openings OP1, is loaded into the processing chamber 102, a silicon source gas, a first source gas, may be supplied to the processing chamber 102 in a pulsed manner for a predetermined period of time through a source supply portion (S11). The silicon source gas may be an organic or inorganic compound incorporating a silicon element. The silicon source gas may contain, for example, hexachlorodisilane (HCDS) or diisopropylaminosilane (DIPAS). The silicon source gas may be adsorbed onto the charge storage layer 364 on the inner walls of the first openings OP1, the upper surface of the epitaxial layer 340, and the upper surface of the hard mask HM1. Subsequently, the first purge gas may be supplied to the processing chamber 102 to perform a first purging operation (S12).

Next, an oxygen source gas, a second source gas, may be supplied to the processing chamber 102 through the nozzle part 140 (S13). The oxygen source gas may be oxygen O₂, ozone O₃, water vapor H₂O, or hydrogen peroxide H₂O₂. The oxygen source gas may react with the previously adsorbed silicon source gas to conformally form the silicon nitride having an atomic layer thickness on the charge storage layer 364 on the inner walls of the first openings OP1, the upper surface of the epitaxial layer 340, and the upper surface of the hard mask HM1. Subsequently, a second purge gas may be supplied to the processing chamber 102 to perform a second purging operation (S12). By repeating the operations (S11 through S14) according to required thicknesses, the tunneling dielectric layer 362 including silicon oxide may be formed.

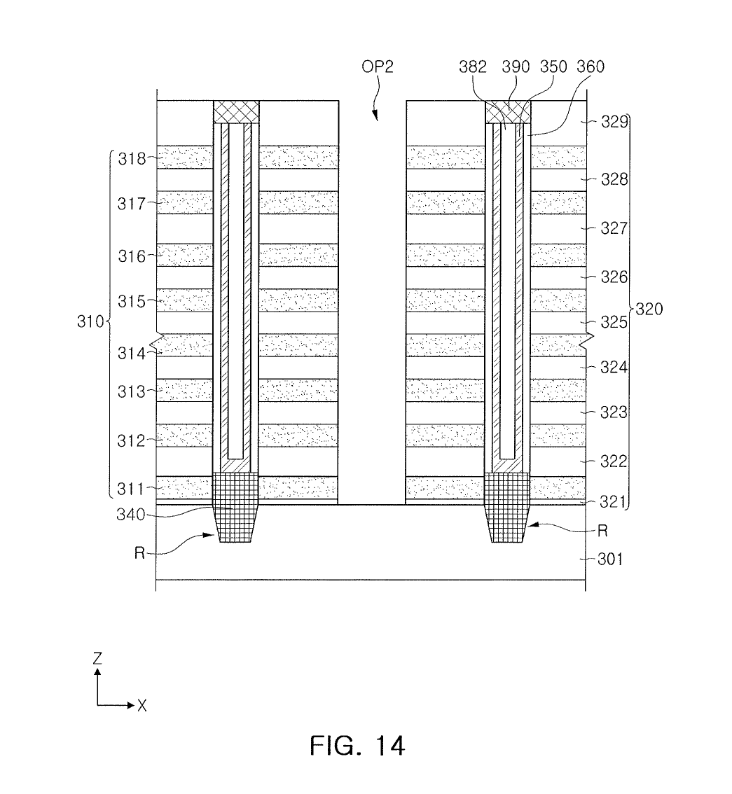

Referring to FIG. 14, removal of a portion of the gate dielectric layer 360 in the first openings OP1 may allow a portion of the upper surface of the epitaxial layer 340 to be exposed, and then the channels 350 may be formed on the exposed epitaxial layer 340 and the gate dielectric layer 360. When a portion of the gate dielectric layer 360 is removed, a portion of the epitaxial layer 340 may be eliminated, and recesses may be formed in upper portions of the epitaxial layer 340. The channels 350 may contact the epitaxial layer 340 on the upper surface of the epitaxial layer 340 to connect thereto. The channels 350 may be formed using polycrystalline silicon or amorphous silicon doped with an impurity or not, and when the channels 350 are formed using the amorphous silicon, a process of crystallizing the amorphous silicon may be additionally performed.

Subsequently, the first insulation layer 382 filling the first openings OP1, and the drain pads 390 may be formed on the channels 35, respectively. The drain pads 390 may be formed by removing portions of the first insulation layer 382, the channels 350, and the gate dielectric layer 360 to form recesses, and by filling the recesses with doped polycrystalline silicon. A chemical mechanical polishing (CMP) process exposing an upper surface of the top interlayer insulation layer 329 may be included.

Next, a second opening OP2 may be formed to separate a stack of the interlayer sacrificial layers 310 and the interlayer insulation layers 320 at a specific interval. The second opening OP2 may be formed by forming a hard mask layer using a photolithography process, and anisotropically etching the stacks of the interlayer sacrificial layers 310 and the interlayer insulation layers 320. The second opening OP2 may have a trench form extending in the y-axis direction (refer to FIG. 9). Before formation of the second opening OP2, the top interlayer insulation layer 329 and the drain pads 390 may have an additional insulation layer formed thereon, and damage to, for example, the drain pads 390 and the channels 350 on lower portions thereof, may be prevented. The second opening OP2 may expose the substrate 301 between the channels 350.

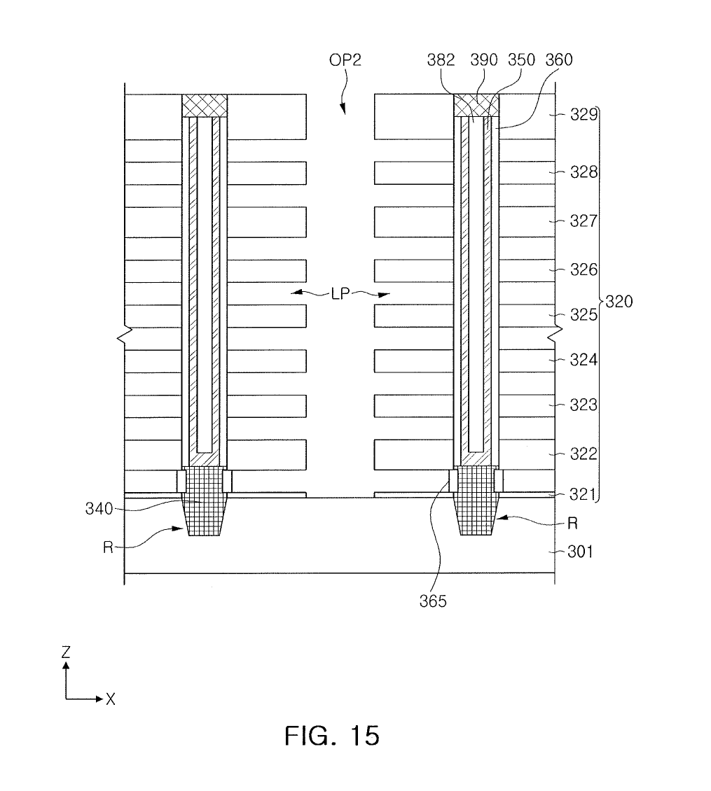

Referring to FIG. 15, the interlayer sacrificial layers 310 exposed through the second opening OP2 may be removed by an etching process, and side openings LP defined between the interlayer insulation layers 320 may be formed. The side openings LP may allow side surfaces of the gate dielectric layer 360 and the epitaxial layer 340 to be partially exposed.

Next, the epitaxial insulation layers 365 may be formed on the epitaxial layer 340 exposed through the side openings LP. The epitaxial insulation layers 365 may be, for example, formed by a thermal oxidation process. In this case, the epitaxial insulation layers 365 may be oxide films formed by oxidizing a portion of the epitaxial layer 340. Thicknesses and shapes of the epitaxial insulation layers 365 are not limited to those illustrated in the example embodiment.

When the thermal oxidation process is performed in the present operation, for the gate dielectric layer 360 exposed through the side openings LP, the damage formed during the etching of the interlayer sacrificial layers 310 may be cured.

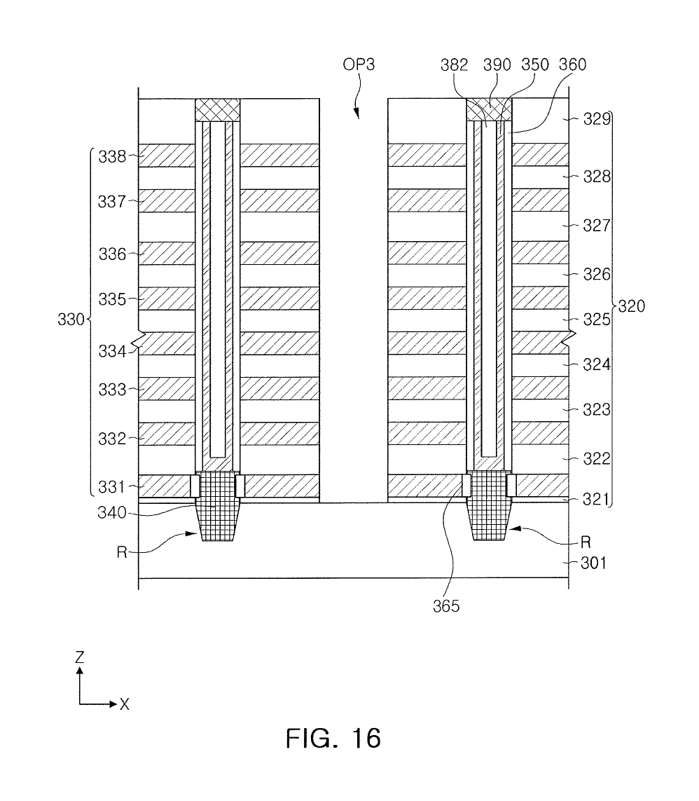

Referring to FIG. 16, the gate electrodes 330 may be formed in the side openings LP, respectively. The gate electrodes 330 may contain a metallic material. According to the example embodiment, the gate electrodes 330 may contain, for example, tungsten (W), aluminum (Al), or copper (Cu). According to the example embodiment, the gate electrodes 330 may further include a diffusion barrier layer. First, the diffusion barrier layer may uniformly cover the interlayer insulation layer 320, the gate dielectric layer 360, the epitaxial insulation layer 365, and the upper surface of the substrate 301 that are exposed through the second opening OP2 and the side openings LP. Next, a metallic material may fill the side openings LP.

Next, in order for the gate electrodes 330 to be respectively disposed only in the side openings LP, a third opening OP3 may be formed by removing a material forming the gate electrodes 330 formed in the second opening OP2 by a mask formation process and an etching process through an additional photolithography process. The third opening OP3 may have a trench form extending in the y-axis direction (refer to FIG. 9).

Resultantly, gate structures including the interlayer insulation layers 320 and the gate electrodes 330 may be formed to be alternately stacked on the substrate 301. The gate electrodes 330 may be exposed through side surfaces of the third opening OP3 formed between the gate structures. The gate structures may include the channels 350 passing through the interlayer insulation layers 320 and the gate electrodes 330 in a direction perpendicular to the upper surface of the substrate 301. The gate structures may also include the epitaxial layers 340 disposed on the substrate 301 on the lower portions of the channels 350, and the gate dielectric layers 360 respectively disposed between the channels 350 and the gate electrodes 330.

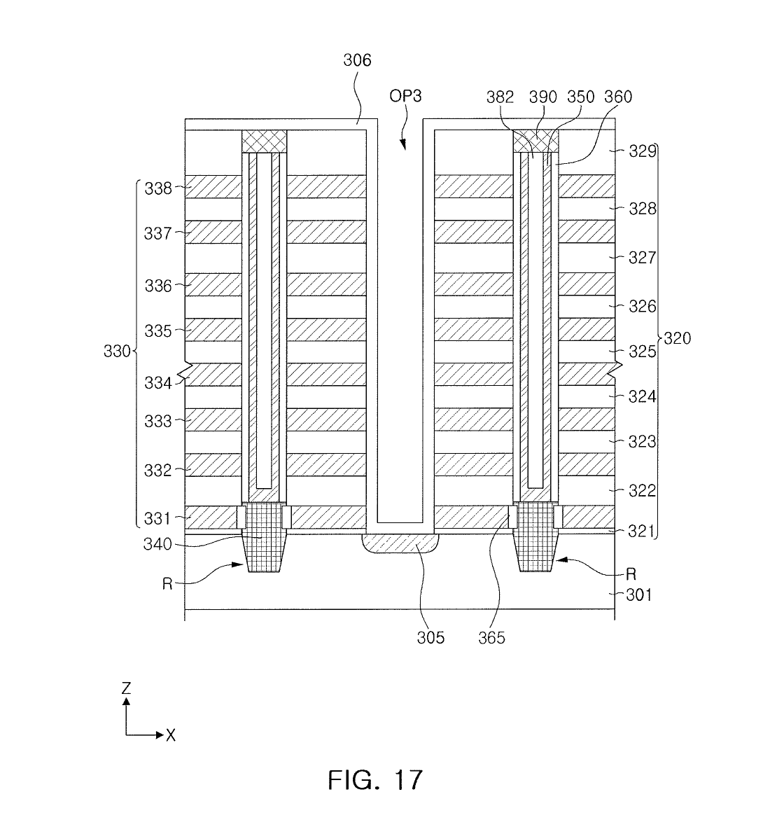

Referring to FIG. 17, the source region 305 may be formed in the substrate 301 exposed through the third opening OP3 between the gate structures, and the second insulation layer 306 may be formed to cover inner walls of the third opening OP3.

First, the source region 305 may be formed by implanting impurity ions into the substrate 301 exposed through the third opening OP3 using the gate structures as a mask.

Next, the second insulation layer 306 may be formed to have a uniform thickness to cover inner side surfaces of the third opening OP3 between the gate structures. The second insulation layer 306 may be, for example, silicon oxide, and the silicon oxide may be formed by atomic layer deposition (ALD) using the atomic layer deposition apparatus 100 illustrated in FIG. 1. Since identical to the above-mentioned method of forming a tunneling insulation layer, a method of forming the second insulation layer 306 will be omitted.

Next, use of an anisotropic etching process may allow a portion of the second insulation layer 306 to be removed so that the source region 305 may be exposed. Resultantly, the second insulation layer 306 may be formed to cover the side surfaces of the gate structures, for example, the inner walls of the third opening OP3. The anisotropic etching process may be used with, for example, reactive ion etching (RIE).

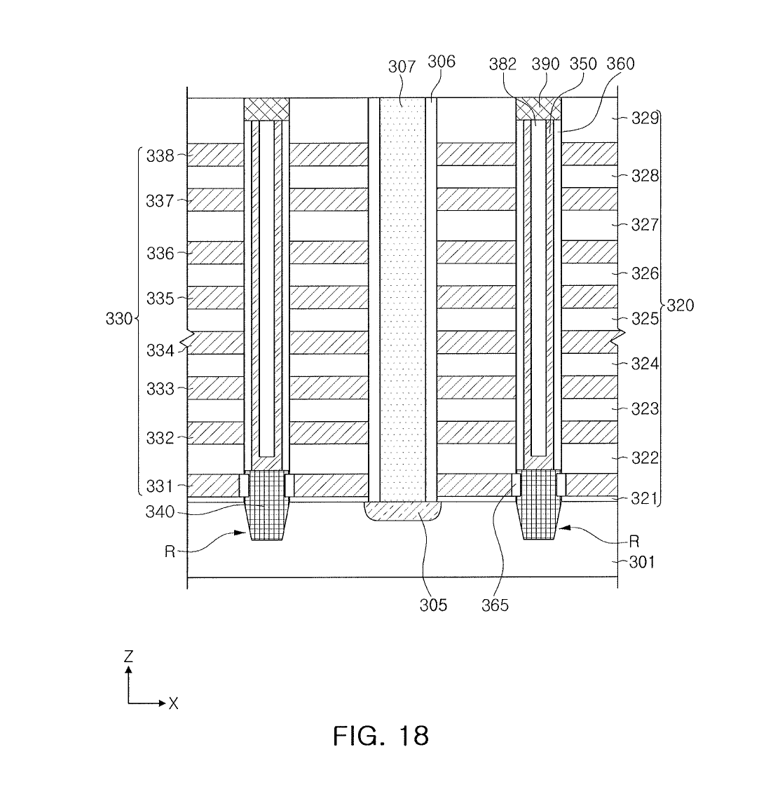

Referring to FIG. 18, the common source line 307 may be formed to be electrically isolated from the plurality of gate electrodes 330 by the second insulation layer 306 on the exposed source region 305.

A process of forming the common source line 307 may include a process of filling the third opening OP3, of which the second insulation layer 306 is formed on the side surfaces, with a conductive material, and a chemical mechanical polishing (CMP) process of exposing the upper surfaces of the top interlayer insulation layer 329 and the drain pads 390.

The conductive material may contain, for example, a metallic material, metal nitride, and a metal silicide material. The common source line 307 may contain, for example, tungsten.

Subsequently, an insulation layer may be formed to cover the common source line 307, the drain pads 390, and the top interlayer insulation layer 329. The insulation layer may have a conductive contact plug formed therein to contact the respective drain pads 390. The insulation layer may have bit lines formed thereon. The drain pads 390 may be electrically connected to the bit lines formed on the insulation layer through the conductive contact plug.

By way of summation and review, when a thin film is formed on form fine patterns having high aspect ratios, excellent step coverage and thickness uniformity may be required. In order to satisfy such requirements, an ALD apparatus forming a thin film layer having a thickness of single atoms may be used.

Since a single-type ALD apparatus processing semiconductor substrates individually may have low productivity, it may be difficult for a single-type ALD apparatus to be used in a semiconductor manufacturing process for mass production, and a batch-type ALD apparatus that may simultaneously process numerous semiconductor substrates may be preferably or required.

A cell stacking process, for example, a process of forming gate dielectric layers (for example, a tunneling layer, a charge trap layer, and a blocking layer in a channel hole), may be performed using batch-type ALD equipment. A thin film processed by batch-type ALD equipment using a manner of supplying a source gas to various regions in a process chamber, for example, top, center, and bottom zones thereof, through a single L-type nozzle pipe, may be deficient in terms of thickness variations between wafers and those in wafers.

According to example embodiments, thickness variations between wafers and those in wafers may be improved by separating a comparative single L-type nozzle pipe into three T-shaped nozzle pipes, and supplying source gases to three regions T, C, and B of a process chamber through three T-shaped nozzle pipes, respectively.

As set forth above, according to example embodiments, providing of a plurality of T-shaped nozzle pipes may allow uniformity in the thickness of individual substrates as well as uniformity between individual substrates when a thin film is formed on one or more substrates by using a batch-type thin film deposition apparatus. Example embodiments may provide a batch-type thin film deposition apparatus that may improve thickness uniformity within individual substrates as well as thickness uniformity between individual substrates.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A thin film deposition apparatus, comprising:
a processing chamber;
a boat in the processing chamber, the boat to accommodate a plurality of substrates therein; and
a nozzle to supply a source gas to the processing chamber to form a thin film on each of the substrates, the nozzle including a plurality of T-shaped nozzle pipes,
each of the T-shaped nozzle pipes including a first pipe having closed ends and a second pipe coupled to a middle portion of the first pipe.

2. The thin film deposition apparatus as claimed in claim 1, wherein the nozzle includes the plurality of T-shaped nozzle pipes spaced apart from each other adjacent to a side surface of the boat.

3. The thin film deposition apparatus as claimed in claim 1, wherein the first and second pipes are coupled to each other to form a substantially right angle.

4. The thin film deposition apparatus as claimed in claim 1, wherein a plurality of the first pipes is linearly adjacent to the side surface of the boat.

5. The thin film deposition apparatus as claimed in claim 1, wherein:
each the first pipes includes a plurality of nozzle holes to sequentially dispense the source gas laterally from each the first pipes, and
each of the second pipes is shorter than the first pipe to which the second pipe is respectively coupled.

6. The thin film deposition apparatus as claimed in claim 5, wherein each of the plurality of nozzle holes corresponds to a space between the plurality of substrates.

7. The thin film deposition apparatus as claimed in claim 1, wherein the plurality of T-shaped nozzle pipes are coupled to each other to be linearly adjacent to the side surface of the boat.

8. The thin film deposition apparatus as claimed in claim 7, wherein:
each of the first pipes includes a first end having a protrusion and a second end having a recess, and
a protrusion of a first first pipe and a recess of a second first pipe are coupled to each other.

9. The thin film deposition apparatus as claimed in claim 1, wherein the plurality of T-shaped nozzle pipes includes a first T-shaped nozzle pipe to supply the source gas to a lower region of the boat, a second T-shaped nozzle pipe to supply the source gas to a central region of the boat, and a third T-shaped nozzle pipe to supply the source gas to an upper region of the boat.

10. The thin film deposition apparatus as claimed in claim 1, wherein the processing chamber includes a plurality of the nozzles.

11. The thin film deposition apparatus as claimed in claim 10, wherein each of the plurality of nozzles sequentially supplies a different source gas.

12. The thin film deposition apparatus as claimed in claim 1, wherein the nozzle further includes:
injection portions respectively connected to the second pipes; and
a coupling portion fixing the injection portions to each other.

13. A thin film deposition apparatus, comprising:
a processing chamber;
a boat in the processing chamber, the boat to accommodate a plurality of substrates therein; and
a plurality of nozzle parts including a plurality of T-shaped nozzle pipes spaced apart from each other adjacent to a side surface of the boat to supply a source gas and a purge gas to form a thin film on each of the substrates to different regions of the processing chamber.

14. The thin film deposition apparatus as claimed in claim 13, wherein each of the plurality of T-shaped nozzle pipes includes a first pipe having a plurality of nozzle holes and a second pipe coupled to a middle portion of the first pipe to form a substantially right angle.

15. The thin film deposition apparatus as claimed in claim 13, wherein:
one of the plurality of nozzle parts supplies the purge gas, and
a remainder of the plurality of nozzle parts supplies the source gas.

16. A thin film deposition apparatus, comprising:
a processing chamber; and
a plurality of nozzle pipes to supply gas to different regions of the processing chamber at substantially uniform velocities.

17. The thin film deposition apparatus as claimed in claim 16, wherein each of the nozzle pipes includes a first pipe having closed ends and a second pipe coupled to a middle portion of the first pipe.

18. The thin film deposition apparatus as claimed in claim 17, wherein the plurality of nozzle pipes is disposed vertically.

19. The thin film deposition apparatus as claimed in claim 18, wherein the plurality of nozzle pipes includes at least three nozzle pipes disposed vertically.

20. The thin film deposition apparatus as claimed in claim 17, where each nozzle pipe includes a separate injection portion to individually supply the gas to each of the nozzle pipes, the separate injection portions respectively connected to the second pipes.
